(19) United States
(12) Patent Application Publication
(10) Pub. No.: US 2014/0109958 A1
(43) Pub. Date: Apr. 24, 2014

(54) METHOD OF IN-SITU FABRICATING INTRINSIC ZINC OXIDE LAYER AND THE PHOTOVOLTAIC DEVICE THEREOF

(71) Applicant: TSMC SOLAR LTD., Taichung City (TW)

(72) Inventors: Shih-Wei CHEN, Kaohsiung City (TW); Wei-Lun XU, Taipei City (TW); Wen-Tsai YEN, Caotun Township (TW); Chung-Hsien WU, Luzhu Township (TW); Wen-Chin LEE, Baoshan Township (TW)

(73) Assignee: TSMC SOLAR LTD., Taichung City (TW)

(21) Appl. No.: 13/654,539

(22) Filed: Oct. 18, 2012

(51) Int. Cl. H01L 31/18; H01L 31/075

(52) U.S. Cl. 136/255; 438/85; 257/E31.017

(57) ABSTRACT

A method of fabricating a photovoltaic device includes forming an absorber layer for photon absorption over a substrate, forming a buffer layer above the absorber layer, wherein both the absorber layer and the buffer layer are semiconductors, and forming a layer of intrinsic zinc oxide above the buffer layer through a hydrothermal reaction in a solution of a zinc-containing salt and an alkaline chemical.

### FIELD

The disclosure relates to photovoltaic devices generally, and more particularly relates to fabrication process of photovoltaic devices and the related structure.

### BACKGROUND

Photovoltaic devices (also referred to as solar cells) absorb sun light and convert light energy into electricity. Photovoltaic devices and manufacturing methods therefor are continually evolving to provide higher conversion efficiency with thinner designs.

Thin film solar cells are based on one or more layers of thin films of photovoltaic materials deposited on a substrate. The film thickness of the photovoltaic materials ranges from several nanometers to tens of micrometers. Examples of such photovoltaic materials include cadmium telluride (CdTe), copper indium gallium selenide (CIGS) and amorphous silicon (α-Si). These materials function as light absorbers. A photovoltaic device can further comprise other thin films such as a buffer layer, a back contact layer, and a front contact layer. Deposition methods such as sputtering and metal organic chemical deposition (MOCVD) are commonly used to form such thin films under medium or high vacuum conditions. Damage and defects can be generated during the process due to the high level of energy associated with the processing conditions, and thin film thickness of the device.

### BRIEF DESCRIPTION OF THE DRAWINGS

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like numerals denote like features throughout specification and drawing.

FIGS. 1A-1C illustrate tendency for damage and difficulty of controlling film thickness, when intrinsic ZnO is deposited above a buffer layer and an absorber layer by methods such as sputtering and MOCVD processes.

FIG. 2 is a flow chart diagram illustrating an exemplary method of fabricating a photovoltaic device comprising forming a layer of intrinsic ZnO through hydrothermal reaction, in accordance with some embodiments.

FIG. 3A is a cross section view of an exemplary back contact layer formed over a substrate, in accordance with some embodiments.

FIG. 3B is a cross section view of an exemplary absorber layer formed above the back contact layer and the substrate of FIG. 3A, in accordance with some embodiments.

FIG. 3C is a cross section view of an exemplary buffer layer formed above the absorber layer of FIG. 3B, in accordance with some embodiments.

FIG. 3D is a cross section view illustrating an exemplary layer of intrinsic ZnO formed above the buffer layer of FIG. 3C, in accordance with some embodiments.

FIG. 4A illustrates an exemplary device during fabrication, where the device comprises a substrate, a back contact layer and an absorber layer, in accordance with some embodiments.

FIG. 4B illustrates formation of a layer of buffer layer on the exemplary device of FIG. 4A, through a chemical bath deposition process, in accordance with some embodiments.

FIG. 4C illustrates formation of a layer of intrinsic ZnO on the exemplary device of FIG. 4B, through a chemical bath deposition process.

FIG. 4D illustrates the exemplary device of FIG. 4C comprising a layer of intrinsic ZnO after being cleaned and dried.

FIG. 5A or 5B is a magnified cross section view of the surface of the exemplary device of FIG. 4D, illustrating exemplary structure of intrinsic ZnO formed above the buffer layer, in accordance with some embodiments.

FIG. 6 is a scanning electron microscopy (SEM) image showing the exemplary structure of intrinsic ZnO formed above the buffer layer, in accordance with some embodiments.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

This disclosure provides a photovoltaic device and the method for making the same to mitigate shunt current and reduce unwanted short circuits in photovoltaic devices. In thin film solar cells, film thickness of the photovoltaic materials such as CdTe, copper indium gallium selenide (CIGS) and amorphous silicon (α-Si), which are formed on a substrate such as glass, ranges from several nanometers to tens of micrometers. Other layers such as the buffer layer, the back contact, and the front contact are even thinner in some embodiments. If the front- and the back contact layers are unintentionally connected because of defects in the thin films, an unwanted short circuit (shunt path) will be provided. Such phenomenon decreases performance of the photovoltaic devices, and can cause the devices to fail to operate within specifications. The loss of efficiency due to the power dissipation resulting from the shunt paths can be up to 100%. Intrinsic zinc oxide (i-ZnO) without any dopants is thus provided above the absorber layer but in between the front- and the back contact layers to prevent short circuiting, which could otherwise occur. Intrinsic ZnO having high electrical resistance can mitigate the shunt current and reduce formation of the shunt paths.

The inventors have determined that certain methods such as sputtering and metal organic chemical deposition (MOCVD) techniques can be suitable for forming such intrinsic ZnO above the buffer layer when performed within certain suitable parameter ranges. Sputtering is a physical process for forming film deposition wherein atoms or molecules are ejected from a solid target material such as ZnO due to bombardment of the target material in a vacuum or inert gas atmosphere. MOCVD is a chemical vapor deposition process in which organic metallic compounds are evaporated in to a processing chamber to react with each other and then are deposited as a film on a substrate. It can be difficult to control film thickness when using either method. The high energy level associated with the sputtering conditions often damages thin films of the buffer layer and/or the absorber layer. In addition, medium or high level vacuum is utilized in both processes, resulting in high cost and low output. However, a controllable method for depositing thinner layer is desired. The inventors have determined that these difficulties can be reduced, particularly for i-ZnO less than 140 nm in thickness for thin film photovoltaic devices, in accordance with some embodiments. The inventors have also determined that i-ZnO layer of less than 140 nm in thickness is suitable to obtain a certain satisfactory photovoltaic device.

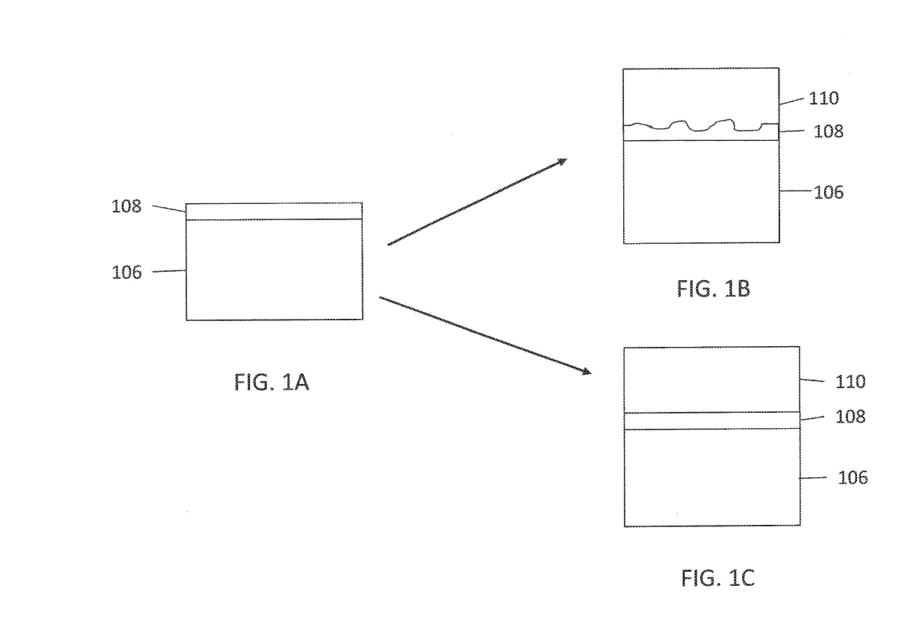

FIGS. 1A-1C illustrate tendency for damage and/or uneven film thickness control when intrinsic ZnO is deposited above a buffer layer 108 and an absorber layer 106 by sputtering and MOCVD processes. A substrate and a back contact layer are present, but not shown in FIGS. 1A-1C, for ease of illustration.

FIG. 1A is a cross section view of a device being fabricated, comprising buffer layer 108 disposed above absorber layer 106. Example of suitable materials for absorber layer 106 include but are not limited to CdTe, copper indium gallium selenide (CIGS) and amorphous silicon (α-Si), in accordance with some embodiments in this disclosure. The thickness of absorber layer 106 is on the order of nanometers or micrometers, for example, 0.5 microns to 10 microns. Examples of buffer layer 108 include but are not limited to CdS or ZnS, in accordance with some embodiments. The thickness of buffer layer 108 is on the order of nanometers, for example, in the range of from 5 nm to 100 nm.

FIGS. 1B and 1C illustrates a layer of intrinsic zinc oxide (i-ZnO) 110 formed above buffer layer 108 and absorber layer 106 by sputtering and MOCVD processes, respectively. A layer of i-ZnO 110 is provided in a monolith film from a continuous deposition process. The film can have polycrystalline structure. However, it can be hard to control the film thickness of layer of i-ZnO. The two processes provide relatively thick films, for example, films of thickness greater than 150 nm. More importantly, a sputtering process can result in a damaged buffer layer 108 and possibly damaged absorber layer 106 due to the high energy level of the sputtered particles which impinge on the substrate. The damage in either absorber layer 106 or buffer layer 108 can deteriorate or destroy the p-n junction formed by absorber layer 108 and buffer layer 108, causing unsatisfactory performance of the resulting photovoltaic device.

This disclosure provides a method for fabricating a photovoltaic device, and the resulting photovoltaic device. In accordance with some embodiments, the method comprises forming an absorber layer for photon absorption over a substrate; forming a buffer layer above the absorber layer; and forming a layer of intrinsic zinc oxide above the buffer layer through a hydrothermal reaction in a solution, which comprises a zinc-containing salt and an alkaline chemical. This disclosure also provides a photovoltaic device comprising an absorber layer over a substrate for photon absorption; a buffer layer disposed above the absorber layer; and a layer of intrinsic zinc oxide of less than 140 nm in thickness disposed above the buffer layer.

Unless expressly indicated otherwise, reference to “hydrothermal reaction” or “chemical bath deposition” in this disclosure will be understood to encompass any reaction in a solution comprising at least one zinc-containing chemical to form zinc oxide at a raised temperature. Reference to “intrinsic zinc oxide” (i-ZnO) in this disclosure will be understood to encompass a material comprising zinc and oxide without any dopant. Reference to “M” as unit of concentration will be understood as “mole/liter.”

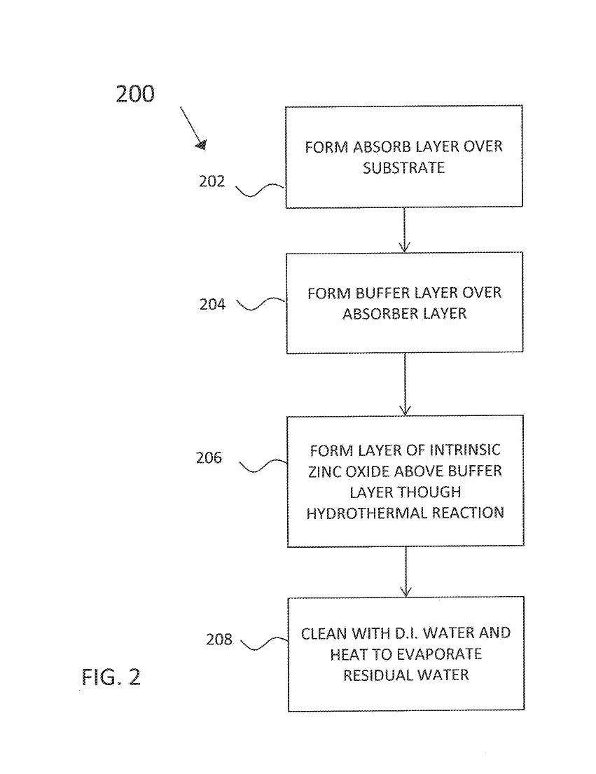

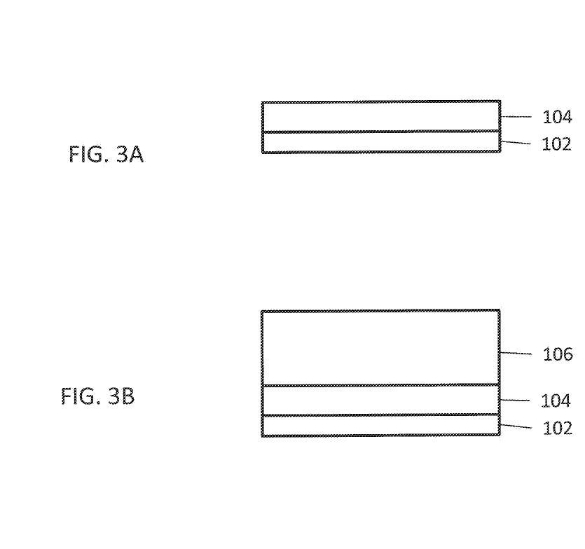

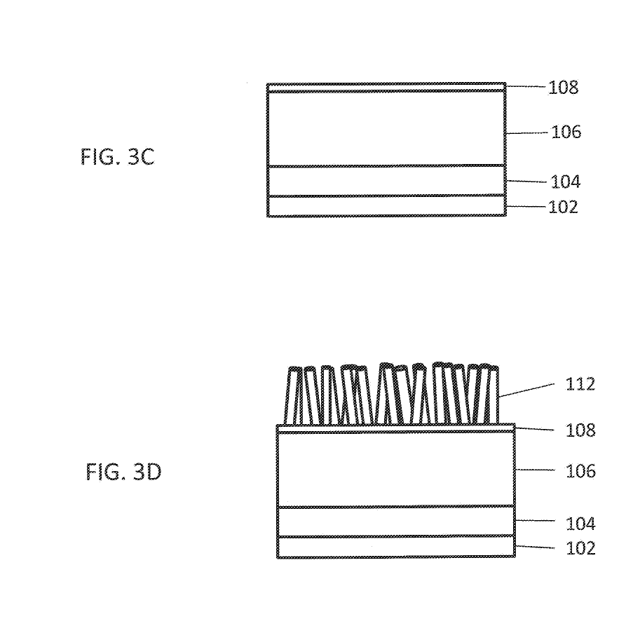

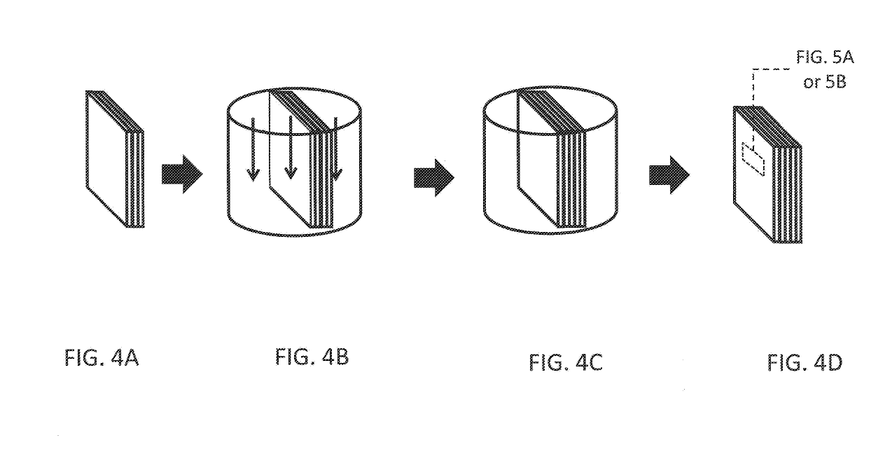

FIG. 2 is a flow chart diagram illustrating an exemplary method 200 of fabricating a photovoltaic device comprising forming a layer of intrinsic ZnO 112 through hydrothermal reaction, in accordance with some embodiments. Exemplary method 200 is also illustrated in FIGS. 3A-3D, in combination with FIGS. 4A-4D. FIGS. 3A-3D illustrate the layered structures of the device being fabricated in each step of method 200 in some embodiments. FIGS. 4A-4D illustrate the processes of hydrothermal reactions used for forming a buffer and a layer of i-ZnO in method 200 in accordance with some embodiments. In the figures, like items are indicated by like reference numerals, and for brevity, descriptions of the structure are not repeated. These drawings are for illustration only and are not in actual scale.

Before step 202 of FIG. 2, a substrate 102 is provided, and a back contact layer 104 is formed above substrate 102. FIG. 3A is a cross section view of an exemplary back contact layer 104 formed over substrate 102, in accordance with some embodiments. Substrate 102 and back contact layer 104 are made of any material suitable for thin film photovoltaic devices. Examples of materials suitable for use in substrate 102 include but are not limited to glass (such as soda lime glass), plastic film and metal sheets. The film thickness of substrate 102 is in the range of 0.1 mm to 5 mm in some embodiments. Examples of suitable materials for back contact layer 104 include, but are not limited to copper, nickel, molybdenum (Mo), or any other metals or conductive material. Back contact layer 104 can be selected based on the type of thin film photovoltaic device. For example, in a CIGS thin film photovoltaic device, back contact layer 104 is Mo in some embodiments. In a CdTe thin film photovoltaic device, back contact layer 104 is copper or nickel in some embodiments.

In step 202 of FIG. 2, an absorber layer 106 for photon absorption is formed over substrate 102 and back contact layer 104. FIG. 3B is a cross section view of an exemplary absorber layer 106 formed above back contact layer 104 and substrate 102 of FIG. 3A, in accordance with some embodiments.

Absorber layer 106 is a p-type or n-type semiconductor material. Examples of materials suitable for absorber layer 106 include but are not limited to cadmium telluride (CdTe), copper indium gallium selenide (CIGS) and amorphous silicon (α-Si). In some embodiments, absorber layer 106 is a semiconductor comprising copper, indium, gallium and selenium, such as CuInₓGa₍₁₋ₓ₎Se₂, where x is in the range of from 0 to 1. In some embodiments, absorber layer 106 is a p-type semiconductor comprising copper, indium, gallium and selenium. Absorber layer 106 has a thickness on the order of nanometers or micrometers, for example, 0.5 microns to 10 microns.

Absorber layer 106 can be formed according to methods such as sputtering, chemical vapor deposition, printing, electrodeposition or the like. For example, CIGS is formed by first sputtering a metal film comprising copper, indium and gallium at a specific ratio, followed by a selenization process of introducing selenium or selenium containing chemicals in gas state into the metal firm. In some embodiments, the selenium is deposited by evaporation physical vapor deposition (PVD).

In step 204 of FIG. 2, a buffer layer 108 is formed above absorber layer 106. FIG. 3C is a cross section view of an exemplary buffer layer 108 formed above absorber layer 106 of FIG. 3B, in accordance with some embodiments.

Buffer layer 108 is an n-type or p-type semiconductor material, depending on the material type of absorber layer 106. Buffer layer 108 and absorber layer 106 form a p-n junction for the photovoltaic device. In some embodiments, absorber layer 106 is CIGS or CdTe, and buffer layer 108 is an n-type semiconductor material. Examples of absorber layer 106 include but are not limited to CdS or ZnS, in accordance with some embodiments. Buffer layer 108 has a thickness on the order of nanometers, for example, in the range of from 5 nm to 100 nm.

Formation of buffer layer 108 is achieved through a suitable process such as sputtering or chemical vapor deposition. For example, in some embodiments, buffer layer 108 is a layer of CdS or ZnS, deposited through a hydrothermal reaction or chemical bath deposition in a solution. Such a process is illustrated in FIGS. 4A-4B.

FIG. 4A illustrates an exemplary device or portion of a device during fabrication. In some embodiments, the device comprises a substrate 102, a back contact layer 104 and an absorber layer 106. FIG. 4B illustrates formation of a layer of buffer layer 108 on the exemplary device of FIG. 4A, through a chemical bath deposition process, in accordance with some embodiments.

Buffer layer 108 can be deposited in a suitable solution at a raised temperature. For example, in some embodiments, a buffer layer 108 comprising a thin film of ZnS is formed above absorber layer 106 comprising CIGS. The buffer layer 108 is formed in an aqueous solution comprising ZnSO₄, ammonia and thiourea at 80° C. A suitable solution comprises 0.16M of ZnSO₄, 7.5M of ammonia, and 0.6 M of thiourea in some embodiments. As shown in FIG. 4B, a device comprising substrate 102, back contact layer 104 and absorber layer 106 is dipped into the solution at 80° C. for 10 to 60 minutes to form a ZnS film of suitable thickness (for example, in the range of from 5 nm to 100 nm) in accordance with some embodiments. In some embodiments, this reaction occurs is in the temperature range of from 50° C. to 70° C.

Referring back to step 206 in FIG. 2, a layer of intrinsic zinc oxide 112 is formed above buffer layer 108 through a hydrothermal reaction or chemical bath deposition in a solution. The solution comprises a zinc-containing salt and an alkaline chemical in accordance with some embodiments. FIG. 4C schematically illustrates the process of forming the layer of i-ZnO 112 on the exemplary device of FIG. 4B, through a chemical bath deposition process. FIG. 3D is a cross section view illustrating an exemplary layer of i-ZnO 112 formed above buffer layer 108 of FIG. 3C.

Any zinc containing salt or other zinc containing chemical can be used. In some embodiments, the zinc-containing salt in the solution for depositing the layer of i-ZnO 112 is selected from the group consisting of zinc nitrate, zinc acetate, zinc chloride, zinc sulfate, combinations and hydrates thereof. One example of hydrate is zinc nitrate hexahydrate. In some embodiments, the zinc-containing salt is zinc nitrate or zinc acetate.

The alkaline chemical in the solution for depositing the layer of i-ZnO 112 is a strong or weak base. In some embodiments, the alkaline chemical is a strong base such as KOH or NaOH. In other embodiments, the alkaline chemical is a weak base or a chemical which can react with water or other solvent to form a weak base. In some embodiments, the alkaline chemical is selected from a group consisting of ammonia, an amine and an amide. In some embodiments, an organic primary, secondary or tertiary amine is used. In some embodiments, the alkaline chemical in the solution is a cyclic tertiary amine, for example, hexamethylenetetramine, as shown by the formula (I):

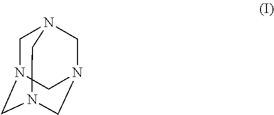

The concentration of the zinc containing salt or the alkaline chemical in the solution is in the range of from 0.01 M to 0.5 M in some embodiments. These two chemicals can be mixed in any ratio. Other additives are optional. In some embodiments, the zinc containing salt or the alkaline chemical in the solution is in the range of from 0.05 M to 0.2 M. The molar ratio of these two chemicals is 1:1 in some embodiments.

In some embodiments, the step of forming the layer of i-ZnO 112 above buffer layer 108 through a hydrothermal reaction in the solution comprises: heating the solution to a temperature in the range of from 50° C. to 100° C.; and immersing the substrate with the absorber layer and the buffer layer thereabove into the solution for a period of time ranging from 0.5 hour to 10 hours, as shown in FIG. 4C.

Before forming layer of i-ZnO 112, treatment or deposition of seeds for i-ZnO on buffer layer 108 is optional. In some embodiments, seeds for i-ZnO are deposited on buffer layer 108. In some other embodiments, the layer of i-ZnO 112 can be directly formed on buffer layer 108 without depositing any seeds for the i-ZnO layer on buffer layer 108. In some embodiments, omitting the step of seed deposition provides a device of better quality and avoids any potential damage to buffer layer 108. Unless expressly indicated otherwise, references to “the layer of i-ZnO directly formed or deposited on buffer layer 108” in this disclosure will be understood to encompass a layer of i-ZnO 112 formed or deposited in contact with the surface of buffer layer 108, which is not treated with any seeds for i-ZnO. References to “the layer of i-ZnO formed or deposited above buffer layer 108” will be understood to encompass a layer of i-ZnO 112 which is or is not in contact with the surface of buffer layer 108. In some embodiments, the layer of i-ZnO 112 is in direct contact with the surface of buffer layer 108, without any other layers such as a seed layer.

In step 208 of FIG. 2, after the layer of i-ZnO 112 is formed above buffer layer 108 through a hydrothermal reaction, method 200 further comprises cleaning the photovoltaic device with a solvent such as deionized water; and heating the photovoltaic device to evaporate residual solvent such as water, in accordance with some embodiments. FIG. 4D illustrates the exemplary device of FIG. 4C comprising a layer of intrinsic ZnO after being cleaned and dried.

In a series of experiments according to this disclosure, an aqueous solution of zinc nitrate (0.1M) and hexamethylenetetramine (0.1 M) was mixed in a glass container, and then heated up to a temperature in the range of from 60-95° C. A substrate 102 of glass having a back contact layer 104 of Mo and an absorber layer 106 of CIGS was immersed into the solution and held for a period of time ranging from 0.5 hour to 10 hours. The sample was then rinsed with deionized water, and heated at 80-120° C., for example, at 90° C., for 5 minutes to evaporate residual water.

The film thickness of the layer of intrinsic zinc oxide (i-ZnO) 112 made by the disclosed method is easy to control. In some embodiments, the layer of i-ZnO 112 is less than 140 nm in thickness. In some embodiments, the layer of i-ZnO 112 is in the range of 5 nm-100 nm in thickness. In some embodiments, such thickness is in the range of 50 nm-90 nm. The formation of the layer of i-ZnO 112 does not cause any significant damage to absorber layer 106 and buffer layer 108.

As illustrated in FIG. 3D, the as-deposited i-ZnO layer 112 in this disclosure can have a smooth or rough surface structure after the chemical bath deposition. The as-deposited i-ZnO layer 112 has a rough surface structure comprising nanotubes, nanorods or nanotips, which are grown vertically on the surface of buffer layer 108, in accordance with some embodiments. Such a surface structure can accelerate growth of other materials such as transparent conductive oxide (TCO) above the layer of i-ZnO subsequently. Such a surface structure also improves light reflection.

In some embodiments, intrinsic ZnO can have crystalline structure. Lower formation rate, which is controlled by factors such as concentration of the chemicals and temperature, can result in higher crystallinity. In some embodiments, layer of i-ZnO 112 is in the structure of hexagonal wurtzite or cubic zincblende.

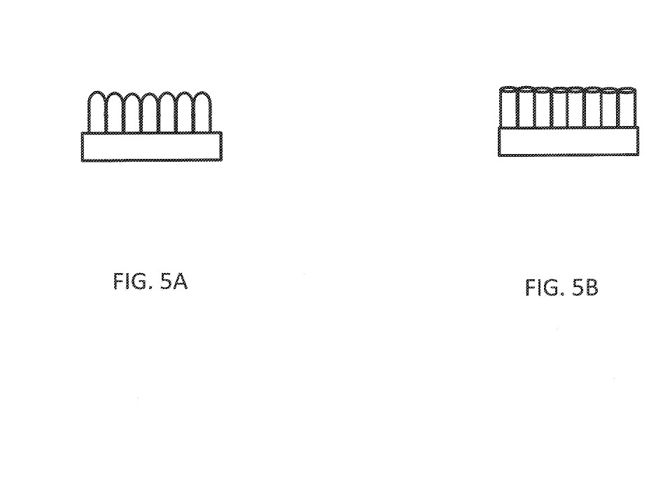

FIGS. 5A and 5B are schematic illustrations of the surface of the device of FIG. 4D, illustrating examples of the surface structure of layer of i-ZnO 112 formed above buffer layer 108, in accordance with some embodiments. As described, i-ZnO can be in the form of nanotubes, nanorods or nanotips. FIGS. 5A and 5B illustrate a nanotip surface structure and a nanorod surface structure, respectively.

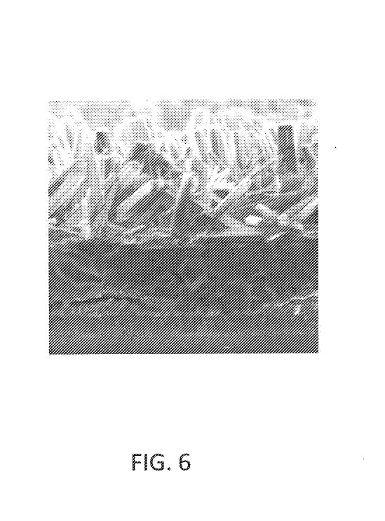

FIG. 6 is a scanning electron microscopy (SEM) image showing the surface structure of a sample of layer of i-ZnO 112 formed above buffer layer 108. This SEM image was obtained from the sample prepared in the experiments using the solution comprising zinc nitrate (0.1M) and hexamethylenetetramine (0.1 M) in the temperature range of from 60-95° C. as described above.

This disclosure also provides a method of fabricating a photovoltaic device. The method comprises forming an absorber layer for photon absorption comprising CuInₓGa₍₁₋ₓ₎Se₂, where x is in the range of from 0 to 1; forming a buffer layer comprising CdS or ZnS above the absorber layer; and forming a layer of i-ZnO directly on the buffer layer through a hydrothermal reaction in a solution. The solution comprises a zinc-containing salt and an alkaline chemical at a temperature in the range from 50° C. to 100° C. The layer of i-ZnO is less than 140 nm in thickness. In some embodiments, the thickness of the layer of i-ZnO is in the range of 5 nm-100 nm. In some embodiments, the thickness of the layer of i-ZnO is in the range of 50 nm-90 nm.

The method described in this disclosure is used as a batch process in some embodiments, and in a continuous mode in some other embodiments. In a continuous mode, a plurality of photovoltaic devices are made continuously in series.

This disclosure also provides a photovoltaic device comprising absorber layer 106 over substrate 102 for photon absorption; buffer layer 108 disposed above absorber layer 106; and layer of i-ZnO of less than 140 nm in thickness disposed above the buffer layer 108. The absorber layer 106 can be a semiconductor comprising copper, indium, gallium and selenium, such as CuInₓGa₍₁₋ₓ₎Se₂, where x is in the range of from 0 to 1. Buffer layer 108 is an n-type semiconductor material such as CdS or ZnS. Layer of i-ZnO 112 is directly disposed on buffer layer 108. Layer of i-ZnO 112 is less than 140 nm in thickness in some embodiments, and is in the range of 5 nm-100 nm in some embodiments. The thickness of layer of i-ZnO 112 is in the range of 50 nm-90 nm.

After layer of i-ZnO 112 is formed above buffer layer 108 according to method 200, a front contact layer (not shown in the drawings) can be formed above layer of i-ZnO 112. An example of front contact is a layer of transparent conductive oxide (TCO) such as indium tin oxide (ITO). Optionally, a layer of antireflection coating (not shown in the drawings) can be further formed thereabove.

This disclosure provides a method for fabricating a photovoltaic device, and the resulting photovoltaic device. In accordance with some embodiments, the method comprises forming an absorber layer for photon absorption over a substrate; forming a buffer layer above the absorber layer; and forming a layer of intrinsic zinc oxide (i-ZnO) above the buffer layer through a hydrothermal reaction in a solution. The solution comprises a zinc-containing salt and an alkaline chemical. Both the absorber layer and the buffer layer are semiconductors, and are configured to form a p-n or n-p junction. In some embodiments, the absorber layer is a semiconductor comprising copper, indium, gallium and selenium, such as CuInₓGa₍₁₋ₓ₎Se₂, where x is in the range of from 0 to 1. The buffer layer can be an n-type semiconductor material, for example, a layer comprising CdS or ZnS. In some embodiments, the zinc-containing salt in the solution is selected from the group consisting of zinc nitrate, zinc acetate, zinc chloride, zinc sulfate, combinations and hydrates thereof. In some embodiments, the alkaline chemical in the solution is selected from a group consisting of ammonia, an amine and an amide. In some embodiments, the zinc-containing salt is zinc nitrate or zinc acetate, and the alkaline chemical is hexamethylenetetramine.

In some embodiments, forming the layer of i-ZnO above the buffer layer through a hydrothermal reaction in the solution comprises heating the solution to a temperature in the range of from 50° C. to 100° C.; and immersing the substrate with the absorber layer and the buffer layer thereabove into the solution for a period of time ranging from 0.5 hour to 10 hours. In some embodiments, forming the layer of intrinsic zinc oxide above the buffer layer further comprises cleaning the photovoltaic device with deionized water after depositing the layer of i-ZnO; and heating the device to evaporate residual water.

In some embodiments, the layer of i-ZnO is directly formed on the buffer layer without depositing any seeds for i-ZnO on the buffer layer. In some embodiments, the layer of i-ZnO in the photovoltaic device made by the disclosed method is less than 140 nm in thickness, for example, in the range of 5 nm-100 nm. In some embodiments, the thickness of the layer of i-ZnO is in the range of 50 nm-90 nm.

This disclosure also provides a method of fabricating a photovoltaic device, comprising forming an absorber layer for photon absorption comprising CuInₓGa₍₁₋ₓ₎Se₂, where x is in the range of from 0 to 1; forming a buffer layer comprising CdS or ZnS above the absorber layer; and forming a layer of i-ZnO directly on the buffer layer through a hydrothermal reaction in a solution comprising a zinc-containing salt and an alkaline chemical at a temperature in the range from 50° C. to 100° C. In some embodiments, the zinc-containing salt is zinc nitrate or zinc acetate, and the alkaline chemical in the solution is hexamethylenetetramine. The layer of i-ZnO is less than 140 nm in thickness, for example, in the range of 5 nm-100 nm. In some embodiments, the thickness of the layer of i-ZnO is in the range of 50 nm-90 nm.

This disclosure also provides a photovoltaic device comprising an absorber layer over a substrate for photon absorption; a buffer layer disposed above the absorber layer; and a layer of i-ZnO of less than 140 nm in thickness disposed above the buffer layer. Both the absorber layer and the buffer layer are semiconductors, and are configured to form a p-n or n-p junction. In some embodiments, the absorber layer is a semiconductor comprising copper, indium, gallium and selenium, such as CuInₓGa₍₁₋ₓ₎Se₂, where x is in the range of from 0 to 1. In some embodiments, the buffer layer is an n-type semiconductor material, for example, a layer comprising CdS or ZnS. In some embodiments, the layer of i-ZnO is directly disposed on the buffer layer. In some embodiments, the layer of i-ZnO in the photovoltaic device is less than 140 nm in thickness, for examples, in the range of 5 nm-100 nm. In some embodiments, the thickness of the layer of i-ZnO is in the range of 50 nm-90 nm.

Although the subject matter has been described in terms of exemplary embodiments, it is not limited thereto. Rather, the appended claims should be construed broadly, to include other variants and embodiments, which may be made by those skilled in the art.

What is claimed is:

1. A method of fabricating a photovoltaic device, comprising:
forming an absorber layer for photon absorption over a substrate;
forming a buffer layer above the absorber layer, wherein both the absorber layer and the buffer layer are semiconductors; and
forming a layer of intrinsic zinc oxide above the buffer layer through a hydrothermal reaction in a solution, the solution comprising a zinc-containing salt and an alkaline chemical.

2. The method of claim 1, wherein the absorber layer is a semiconductor comprising copper, indium, gallium and selenium.

3. The method of claim 2, wherein the absorber layer is CuInₓGa₍₁₋ₓ₎Se₂, where x is in the range of from 0 to 1.

4. The method of claim 1, wherein the buffer layer is an n-type semiconductor material.

5. The method of claim 4, wherein the buffer layer comprises CdS or ZnS.

6. The method of claim 1, wherein the zinc-containing salt in the solution for depositing the layer of intrinsic zinc oxide is selected from the group consisting of zinc nitrate, zinc acetate, zinc chloride, zinc sulfate, combinations and hydrates thereof.

7. The method of claim 6, wherein the zinc-containing salt is zinc nitrate or zinc acetate.

8. The method of claim 1, wherein the alkaline chemical in the solution for depositing the layer of intrinsic zinc oxide is selected from a group consisting of ammonia, an amine and an amide.

9. The method of claim 8, wherein the alkaline chemical in the solution is hexamethylenetetramine.

10. The method of claim 1, wherein forming the layer of intrinsic zinc oxide above the buffer layer through a hydrothermal reaction in the solution comprises:
heating the solution to a temperature in the range of from 50 to 100° C.; and
immersing the substrate with the absorber layer and the buffer layer thereabove into the solution for a period of time ranging from 0.5 to 10 hours.

11. The method of claim 10, further comprising:
cleaning the photovoltaic device with deionized water after depositing the layer of intrinsic zinc oxide; and
heating the photovoltaic device to evaporate residual water.

12. The method of claim 1, wherein the layer of intrinsic zinc oxide is directly formed on the buffer layer without depositing any seeds for intrinsic zinc oxide on the buffer layer.

13. The method of claim 1, wherein the layer of intrinsic zinc oxide in the photovoltaic device is less than 140 nm in thickness.

14. The method of claim 13, the thickness of the layer of the intrinsic zinc oxide in the photovoltaic device is in the range of 5 nm-100 nm.

15. A method of fabricating a photovoltaic device, comprising:
forming an absorber layer for photon absorption comprising CuInₓGa₍₁₋ₓ₎Se₂, where x is in the range of from 0 to 1;
forming a buffer layer comprising CdS or ZnS above the absorber layer; and
forming a layer of intrinsic zinc oxide directly on the buffer layer through a hydrothermal reaction in a solution comprising a zinc-containing salt and an alkaline chemical at a temperature in the range from 50° C. to 100° C.
wherein the layer of intrinsic zinc oxide is less than 140 nm in thickness.

16. The method of claim 15, wherein the zinc-containing salt is zinc nitrate or zinc acetate, and the alkaline chemical in the solution is hexamethylenetetramine.

17. The method of claim 15, the thickness of the layer of the intrinsic zinc oxide in the photovoltaic device is in the range of 5 nm-100 nm.

18. A photovoltaic device comprising:
an absorber layer over a substrate for photon absorption;
a buffer layer disposed above the absorber layer, wherein both the absorber layer and the buffer layer are semiconductors; and
a layer of intrinsic zinc oxide of less than 140 nm in thickness disposed above the buffer layer.

19. The photovoltaic device of claim 18, wherein:
the absorber layer comprises CuInₓGa₍₁₋ₓ₎Se₂, where x is in the range of from 0 to 1;
the buffer layer comprises CdS or ZnS;
and the layer of intrinsic zinc oxide is directly disposed on the buffer layer.

20. The photovoltaic device of claim 18, wherein the thickness of the layer of intrinsic zinc oxide is in the range of 50 nm-90 nm.
